(19) United States
(12) Patent Application Publication
(10) Pub. No.: US 2026/0038599 A1
(43) Pub. Date: Feb. 5, 2026

(54) PROGRAMMING DUMMY DATA OR PERFORMING FLASH WRITE ON PARTIALLY PROGRAMMED MEMORY BLOCKS OF VIRTUAL BLOCKS

(71) Applicant: Microchip Technology Incorporated, Chandler, AZ (US)

(72) Inventors: Pitamber SHUKLA, San Jose, CA (US); Saswati DAS, Milpitas, CA (US); Nian Niles YANG, Mountain View, CA (US); Tim James SYMONS, Anmore (CA)

(21) Appl. No.: 19/021,154

(22) Filed: Jan. 14, 2025

Related U.S. Application Data
(60) Provisional application No. 63/678,016, filed on Jul. 31, 2024.

(51) Int. Cl. G11C 16/16; G11C 16/08; G11C 16/10

(52) U.S. Cl. CPC G11C 16/16; G11C 16/08; G11C 16/102

(57) ABSTRACT

A controller may detect an event occurring on a solid state device. The event may include at least one of: a program error on a physical block of a first virtual block, a read error on the physical block, or a power cycle of the solid state drive. The controller may program user data stored in the first virtual block onto a second virtual block based on detecting the event. The controller may include the first virtual block in a pool of virtual blocks scheduled for erase operations. When the first virtual block is in the open state, the controller may program dummy data on the first virtual block prior to performing an erase operation on the virtual block, or perform a flash write operation on the first virtual block prior to performing the erase operation on the virtual block.

### RELATED APPLICATION

This application claims priority to U.S. Provisional Patent Application No. 63/678,016 entitled “PROGRAMMING DUMMY DATA OR PERFORMING FLASH WRITE ON PARTIALLY PROGRAMMED MEMORY BLOCKS OF VIRTUAL BLOCKS,” filed Jul. 31, 2024, which is incorporated herein by reference in its entirety.

### FIELD

The present disclosure generally relates to partially corrupted memory blocks of non-volatile memory devices and, for example, to performing programming operations on partially corrupted memory blocks.

### BACKGROUND

A non-volatile memory device may include a memory device that may store and retain data without external power supply. One example of a non-volatile memory device is a NAND flash memory device. In some situations, one or more NAND flash memory devices may be included in a storage device, such as a solid-state drive (SSD). The one or more NAND flash memory devices may store data that is used by a host computing device. The SSD may include a controller that controls operations performed on the SSD. The operations may include read operations, write operations, and erase operations.

### SUMMARY

A method may comprise detecting an event occurring on a solid state drive, wherein the event includes at least one of: a program error on a physical block of a first virtual block, a read error on the physical block, or a power cycle of the solid state drive; programming user data stored in the first virtual block onto a second virtual block based on detecting the event; including the first virtual block in a pool of virtual blocks scheduled for erase operations; determining whether the first virtual block is in an open state; and when the first virtual block is in the open state: programming dummy data on the first virtual block prior to performing an erase operation on the virtual block, or performing a flash write operation on the first virtual block prior to performing the erase operation on the virtual block.

A system may comprise: a controller to: detect an event associated with a virtual block, wherein the event includes at least one of: a program error on a physical block of the virtual block, a read error on the physical block, or a power cycle of a storage device that includes the virtual block; determine whether the virtual block is in an open state; program data on the virtual block, prior to performing an erase operation on the virtual block, when the virtual block is in the open state; and perform the erase operation on the virtual block, without programming the data on the virtual block, when the virtual block is not in the open state.

A non-transitory computer-readable medium may store a set of instructions, the set of instructions comprising: one or more instructions that, when executed by one or more processors of a controller, cause the controller to: detect an event associated with a first virtual block, wherein the event includes at least one of: a program error on a physical block of the first virtual block, a read error on the physical block, or a power cycle of a storage device that includes the first virtual block; program user data stored in the first virtual block onto a second virtual block based on detecting the event; and program data on the first virtual block, prior to performing an erase operation on the first virtual block, when the first virtual block is in an open state.

### BRIEF DESCRIPTION OF THE DRAWINGS

FIG. 1 is a diagram of an example implementation described herein.

FIGS. 2A-2C are diagrams of an example of virtual blocks described herein.

FIG. 3 is a flowchart of an example process associated with performing an erase operation on partially programmed blocks of a virtual block.

FIG. 4 is a flowchart of an example process associated with performing an erase operation on partially programmed blocks of a virtual block.

### DETAILED DESCRIPTION

The following detailed description of example implementations refers to the accompanying drawings. The same reference numbers in different drawings may identify the same or similar elements.

A non-volatile memory device may include a storage medium that may store and retain data without external power supply. One example of a storage medium is a NAND flash memory device. A solid state drive (SSD) may include multiple non-volatile memory devices.

A non-volatile memory device (or a die of the non-volatile memory device) may include multiple planes. A plane may include multiple blocks, and a block may include multiple wordlines. A wordline may include one or more pages.

In some situations, the multiple non-volatile memory devices (or dies of the multiple non-volatile memory devices) may form a virtual block (VB). The VB may refer to a collection of blocks (e.g., memory blocks or physical memory blocks) across all logical unit numbers (LUNs). For example, the blocks may be blocks of different dies of the multiple non-volatile memory devices. The blocks, included in the VB, may have a same number of program/erase (P/E) cycles. In other words, the blocks may be subject to the same number of program/erase (P/E) cycles.

The size of a VB may be based on a quantity of channels, a quantity of targets, a quantity of LUNs, and a physical block size ([#Channels]×[#Targets]×[#LUNs]×[Physical Block Size]). The size of the VB may potentially vary according to a number of blocks that may not be used to store data (also referred to as “bad blocks”). In some situations, the VB may include multiple virtual pages. The virtual pages may refer to a collection of pages across all LUNs in a VB.

A controller of the SSD may maintain a pool of VBs for storing system data and a separate pool of VBs for storing user data. As used herein, “a pool of VBs,” may refer to a group of VBs. The system data may be stored on single-level cell (SLC) blocks (e.g., blocks with SLC cells) due to the high reliability requirement for the system data. The user data may be stored on triple-level cell (TLC) blocks (e.g., blocks with TLC cells). In some implementations, data may be stored on SLC blocks alone, on multi-level cell (MLC) blocks, on TLC blocks alone, or on quad-level cell (QLC) blocks alone, In some implementations, data may be stored on a combination of SLC blocks, MLC blocks (e.g., blocks with MLC cells), TLC blocks, and QLC blocks (e.g., blocks with QLC cells), Some blocks may be reserved per die to be replacements for bad blocks.

A VB may be an open VB or a closed VB. An “open VB” (or, in other words, a VB in an open state) may refer to a VB that has one or more empty or available wordlines. A wordline may be “empty” or “available” when the wordline is available to store data. Conversely, a “closed VB” (or, in other words, a VB in a closed state) may refer to a VB with all wordlines programmed (e.g., a VB with no “empty” or “available” wordlines).

Typically, if an open VB experiences a program error or a read error, the controller of the SSD may schedule the open VB for an erase operation. Similarly, if the SSD undergoes a power cycle, the open VB may be scheduled for erase operations. A “power cycle” may refer to a condition during which the SSD experiences loss of power (e.g., the SSD is turned off and then turned on).

In the above mentioned situations regarding the errors and the power cycle, in an effort to prevent any data integrity impact on the SSD and on valid data (e.g., user data) stored by the open VB, the controller may move the valid data from the open VB to another VB. Additionally, the controller may issue an erase command to cause an erase operation to be performed on the open VB.

In some situations, at the time the erase operation is performed, the open VB may include multiple partially programmed blocks. A partially programmed block may refer to a block that is partially programmed (e.g., a block with one or more wordlines that are not programmed). For example, a partially programmed block may include a programmed portion and an unprogrammed portion. The programmed portion may include programmed wordlines and the unprogrammed portion may include unprogrammed wordlines. Subjecting the partially programmed blocks to multiple erase operations may reduce a reliability of cells of the partially programmed blocks. The reduced reliability of the cells may increase programming latency and read latency during an operation of the SSD. Additionally, as the SSD ages, programming latency and read latency during an operation of the SSD may increase.

Typically, erase and program operations involves high electric field, which in turn damages an insulating oxide layer of the wordlines of the blocks. Typically, for SSDs, erase operations are performed on a block level. The damage to the oxide layer will lead to poor reliability of the SSD and reduced endurance/lifetime of the SSD. Performing multiple erase operations on the unprogrammed wordlines (of partially programmed blocks) will cause a more severe damage to the insulating oxide layer. The damage to the insulating oxide layer will lead to poor reliability and lead to the blocks becoming corrupted. Corrupted blocks may lead to system yield loss (e.g., lead decrease of available physical locations for storing data). The above-mentioned problem may increase as the SSD ages. As mentioned herein, for SSDs, an erase operation is performed on a block level. In this regard, consider a block (of a VB) with 100 wordlines. Assume the first 50 wordlines (e.g., wordlines 0 to 49) are in a programmed stated (e.g., are programmed) whereas the last 50 wordlines (e.g., wordlines 50-99) are in an erase state (e.g., are not programmed). In this regard, the block may be a partially programmed block. When an erase operation is performed on the block, the last 50 wordlines (e.g., wordlines 50-99) will be deeper erased because the last 50 wordlines were in the erase state (e.g., were not programmed) prior to the erase operation. When an additional erase operation is performed on the block, the last 50 wordlines will be erased again and, accordingly, will be further deeper erased. As a result of the last 50 wordlines being subjected to multiple erase operations (performed on the block) after being initially in the erase state, the last 50 wordlines may be in a condition referred to as a “deeper erase condition.” On the other hand, because the first 50 wordlines were initially in the programmed state, by being subjected to multiple erase operations (performed on the block) after being initially in the programmed state, the first 50 wordlines may be in a condition referred to as a “shallow erase condition.” For example, the first 50 wordlines may be in a shallow erase condition compared to the last 50 wordlines. Conversely, the last 50 wordlines may be in a deeper erase condition compared to the first 50 wordlines. In this regard, a string current during an erase verify operation will be higher for the partially programmed block compared to a string current of a fully programmed block. As used herein, a “string current” may refer to a current flowing through a bit line (or string) during an operation on the SSD. The bitline may connect multiple wordlines. For example, the programmed wordlines (e.g., the first 50 wordlines) of the block will have a higher string current during an erase operation compared to a fully programmed block.

As an example, a threshold voltage of cells of the last 50 worldlines may exceed a threshold voltage of cells of the first 50 wordlines. While the first 50 wordlines may pass the erase verify operation, the first 50 wordlines may not have actually been erased completely, but may have rather been subjected to shallow erase in terms of the threshold voltage distribution of memory cells of the first 50 wordlines. The threshold voltage of the memory cells may be higher than a threshold voltage of memory cells that have been fully erased.

The reduced performance and the increased number of corrupted blocks may reduce a capacity of the SSD as the SSD ages. Typically, a reliability of the SSD decreases as the age of the non-volatile memory device increases. The decrease in reliability leads to an increase in read errors, program errors, or a combination of read errors and program errors.

Without a management solution for partially programmed blocks, a cell capability (of the cells of the VB) is not fully utilized because the partially programmed blocks may be scheduled for an erase operation before all wordlines have been programmed. Additionally, without a management solution for partially programmed blocks, unprogrammed wordlines may be erased multiple times.

Typically, erase and program operations involve significant electric field, which in turn damages an insulating oxide layer of a cell. Damage to the insulating oxide layer leads to poor reliability of the SSD, reduced endurance of the SSD, and reduced lifetime of the SSD. Performing multiple erase operations on the unprogrammed wordlines will cause more damage to insulating oxide layers of the unprogrammed wordlines than to programmed wordlines. The damage to the insulating oxide layers may lead to a decreased reliability of cells and an increased number of corrupted blocks with aging of the SSD.

The increased number of corrupted blocks may lead to system yield loss, thereby resulting in a reduced storage capacity of the SSD. To compensate for predetermined projected system yield loss resulting from the increased number of corrupted blocks, spare blocks may be allocated to maintain a capacity of the SSD, which in turn can increase a cost associated with the SSD, can reduce a lifetime of the SSD, or a combination of both.

In existing SSDs, the controller does not attempt to mitigate the reliability risk caused by erase operations performed on a partially programmed block. Therefore, multiple erase operations may be performed on the partially programmed block (during a lifetime of the SSD) and the multiple erase operations may lead to severe degradation of the cells of the partially programmed block. Existing solutions (for erase operations performed on the partially programmed block) may decrease a reliability of the cells, which can significantly reduce the lifetime of the SSD drives as well as the quality of service (QoS).

Implementations described herein provide a technical solution to the technical problems discussed above with respect to erase operations performed on one or more partially programmed blocks of an open VB (or, in other words, a VB in an open state). In this regard, the technical solution is directed to performing a write operation of random data (e.g., referred to as “dummy data”) or performing a flash write operation on the one or more partially programmed blocks before an erase operation on the one or more partially programmed blocks. A flash write operation is performed at a speed that exceeds a speed at which a write operation of dummy data is performed. Accordingly, a flash operation may be performed (instead of a write operation of dummy data) if one or more other operations are to be performed within a relatively short period of time. The one or mor other operations may be operations requested by a host device. A flash write operation may refer to a write (or programming) operation that is performed on an entirety of a block. A write operation of dummy data may refer to a write (or programming) operation that is performed on unprogrammed wordlines. A write operation of dummy data may be performed as a background operation. In this regard, if a quantity of unprogrammed wordlines exceeds a quantity threshold, a flash write operation may be performed instead of a write operation of dummy data. Based on the foregoing, a controller or a host device may select a flash write operation or a write operation of dummy data based on a data usage goal, a timelines/speed goal, and/or a performance goal, without limitation. Performing a write operation of dummy data or performing a flash write will significantly improve cell reliability of cells of the one or more partially programmed blocks and, therefore, will enhance a lifetime of the SSD as well as the QoS.

In some situations, a controller may detect that a VB (of an SSD) is experiencing an error (e.g., a program error or a read error) independent of a power loss on the SSD. Alternatively, the controller may detect a power loss on the SSD and may identify a VB after power has restored following the power loss. In some examples, the VB (identified after power has been restored) may be included in a pool of VBs that are to undergo an erase operation after the power loss. In some examples, the VB (identified after power has been restored) may be a VB that is experiencing an error (e.g., a program error or a read error). The controller may perform the write operation of dummy data or the flash write operation on the VB (identified after power has been restored) based on identifying the VB after power has been restored. In some situations, the controller may perform the write operation of dummy data or perform the flash write operation (on the VB experiencing the error independent of the power loss) after the controller detects an error during a programming operation or a read operation. In other words, the controller may perform the write operation of dummy data or perform the flash write operation after the controller detects a programming error or a read error. In some examples, the controller may detect a threshold number of errors before performing the write operation of dummy data or perform the flash write operation. Additionally, or alternatively, the controller may detect a threshold number of blocks (of the partially programmed block) that are experiencing programming errors or read errors before performing the write operation of dummy data or perform the flash write operation. The controller may move data from the partially programmed block to another block before performing the write operation of dummy data. The write operation may be performed on SLC blocks, MLC blocks, TLC blocks, or QLC blocks. The write operation may be performed at a various voltage levels.

In some implementations, the controller may determine whether the VB (that includes the partially programmed block) is an open VB prior to performing the write operation of dummy data or the flash write operation. In some examples, the controller may determine whether the VB is an open VB based on VB information. The VB information may include a data structure that stores information regarding the VB. For example, the VB information may include information indicating whether the VB is an open VB or is a closed VB, information indicating whether the VB includes partially programmed blocks, information identifying the partially programmed blocks, and/or information identifying unprogrammed wordlines of the partially programmed blocks, among other examples.

In some examples, the flash write operation may be performed on an entirety of the partially programmed block. The flash write operation may be performed using a write pulse, which is a single pulse to globally program cells of all wordlines of the partially programmed block simultaneously. In some examples, by using the flash write operation, all the wordlines may be programmed simultaneously to a high threshold state. In this regard, the data on the wordlines may become corrupted and not readable. The controller may issue a command that identifies the partially programmed block and that identifies data (e.g., bits) to be written to the partially programmed block. The wordlines may be programmed to a selected programming state regardless of existing programming states that cells (of the wordlines) are in (e.g., without a verify operation to verify a programming state of the wordlines).

In some examples, the dummy data may be programmed on unprogrammed wordlines of the partially programmed block. A partially programmed block may include a programmed portion and an unprogrammed portion. The programmed portion may include programmed wordlines and the unprogrammed portion may include unprogrammed wordlines.

The dummy data may include one or more bits. In some examples, the one or more bits may be predetermined by the controller. In some examples, the one or more bits may be randomly selected by the controller. In some examples, the controller may determine the dummy data (e.g., a pattern of the dummy data) by taking into consideration overage associated with operations performed on the memory device and/or associated with power consumption of the memory device. In some examples, the dummy data may be an SLC random pattern (e.g., random data programmed using one bit per cell). In this regard, if the block is partially programmed using SLC programming (e.g., programming using one bit per cell), then the dummy data may be the SLC data pattern. In some examples, the dummy data may be a TLC random pattern (e.g., random data programmed using three bits per cell). In this regard, if the block is partially programmed using TLC programming (e.g., programming using three bits per cell), then the dummy data may be the TLC data pattern. In some examples, the dummy data may be a QLC random pattern (e.g., random data programmed using four bits per cell). In this regard, if the block is partially programmed using QLC programming (e.g., programming using four bits per cell), then the dummy data may be the QLC data pattern. In some examples, the dummy data may be a repetitive value. In some examples, the repetitive value may represent a charge state of a memory cell. The repetitive value may be referred to as a “fixed pattern” (or as “solid pattern”). In some examples, the repetitive value may be randomly selected from all possible repetitive values (e.g., selected from values representing all possible charge state of a memory cell). In this regard, the dummy data (e.g., the repetitive value randomly selected) may be referred to as a “solid level random pattern” (or as “random pattern”). In some examples, the data used for the dummy data may match a type of memory cells in which the dummy data is to be stored.

Overall, the controller may determine a pattern for the dummy data by considering a programming power usage overhead. For example, determining a pattern for the dummy data may involve use of additional data (e.g., additional with respect to existing user data). In this regard, the dummy data may be determined by allocating resources for determining a pattern for the dummy data. For example, determining the dummy data may consume resources of the SSD, such as computing resources and/or power supplied to the SSD. Accordingly, in anticipation of performing a write operation of dummy data, the controller may allocate resources that may be used to determine the dummy data. As explained herein, the resources may include computing resources and/or power. The pattern of the dummy data may refer to the repetitive value or the random values.

In some implementations, the dummy data may include a pattern of bits that matches a pattern of bits stored by the programmed wordlines. In some examples, the pattern of bits (of the dummy data) may match an entirety of the pattern of bits stored by the programmed wordlines. In some examples, the pattern of bits (of the dummy data) may match a portion of the pattern of bits stored by the programmed wordlines. In some examples, the portion of the pattern of bits (of the dummy data) may be predetermined by the controller. In some examples, the portion of the pattern of bits (of the dummy data) may be randomly selected by the controller.

In some implementations, the dummy data may include random data. In some implementations, the dummy data may include predetermined data.

In some examples, the controller may perform the flash write operation or program the dummy data as a background operation. After the controller performs the flash write operation or programs the dummy data, the controller may cause an erase operation to be performed on the VB. By performing the flash write operation or programming the dummy data prior to the erase operation, the controller may significantly improve the cell reliability of the SSD and improve the QoS throughout a lifetime of the SSD.

Overall, implementations described herein may handle the partially programmed blocks differently compared to the fully programmed blocks, which will significantly improve the cell reliability of the SSD and improve the QoS throughout a lifetime of the SSD.

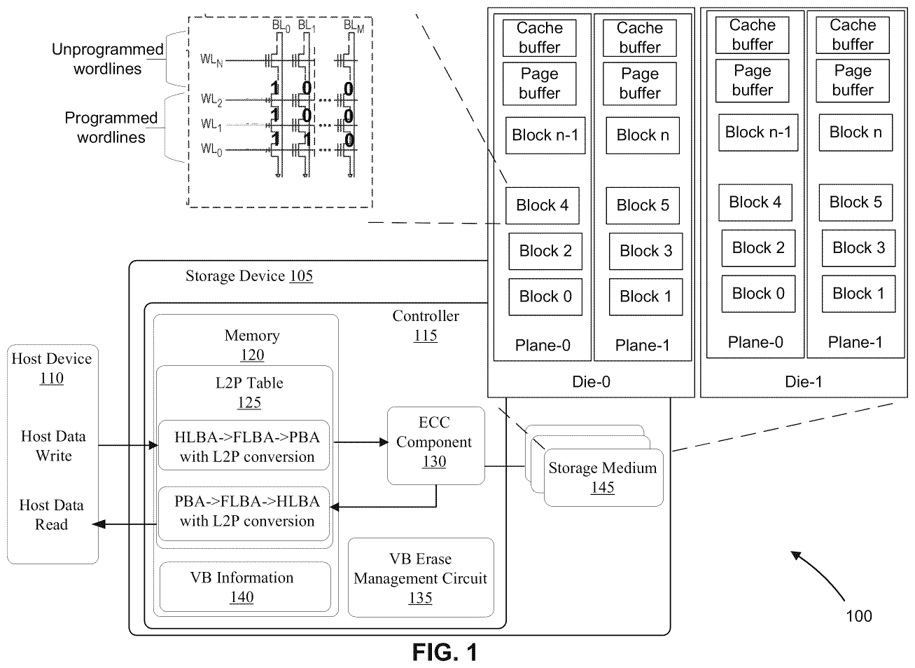

FIG. 1 is a diagram of an example implementation 100 described herein. Example implementation 100 describes components and operations associated with a storage device 105. In some implementations, storage device 105 may include a solid state drive (SSD). As shown in FIG. 1, storage device 105 may be associated with a host device 110. Host device 110 may access data (also referred to as “host data”) stored by storage device 105. For example, as shown in FIG. 1, host device 110 may initiate a host read operation (e.g., a read operation) to read the host data from storage device 105.

Host device 110 may include one or more devices capable of receiving, generating, storing, processing, and/or providing information associated with generating a logical to physical (L2P) data structure (or L2P table), as described herein. The host device 110 may include a communication device and a computing device. For example, the host device 110 may include a wireless communication device, a mobile phone, a user equipment, a laptop computer, a tablet computer, a desktop computer, a wearable communication device (e.g., a smart wristwatch, a pair of smart eyeglasses, a head mounted display, or a virtual reality headset), or a similar type of device.

As shown in FIG. 1, storage device 105 may include a controller 115. Controller 115 may include one or more of an application specific integrated circuit (ASIC) or firmware. Controller 115 may cause functions to be performed on storage device 105, such as read operations, write operations, erase operations, and garbage collection operations, among other examples. Controller 115 may include a memory 120 and an error correction code (ECC) component 130. Memory 120 may include a RAM (e.g., dynamic random access memory (DRAM), a synchronous DRAM (SDRAM), among other examples).

As shown in FIG. 1, memory 120 may include an L2P table 125 (or an L2P data structure). L2P table 125 may store a mapping between host logical block addresses (or logical addresses identified by host device 110) and physical block addresses (or physical addresses of non-volatile memory devices of storage device 105). In some implementations, L2P table 125 may be generated by controller 115.

In some implementations, controller 115 may identify a host logical block address (HLBA) associated with the host data by which host device 110 may reference the host data in a future read operation. As shown in FIG. 1, controller 115 may convert the HLBA to a flash logical block address (FLBA) or other local logical block address, and then may link the FLBA to a physical block address (PBA) using an L2P conversion process. Conversely, controller 115 may convert a PBA to an FLBA or other local logical block address, and then may link the FLBA to a HLBA using a physical to logical (P2L) conversion process. In this way, the host device may send a static address associated with the host data, controller 115 may link the address known to host device 110 to an address known to storage device 105 (the FLBA), and may link the address known to storage device 105 to a physical address of the host data within a storage medium of storage device 105.

Controller 115 may store the links between the HLBA, the FLBA, and the PBA in L2P table 125. In some aspects, the host data may be moved within the storage medium or between storage mediums of storage device 105, which controller 115 may note in the link between the FLBA and the physical location. In this way, the HLBA may bypass being updated when the host data is moved to a new PBA.

ECC component 130 may include an ECC engine. ECC component 130 may perform error correction code encoding on the host data. In some implementations, the error correction code encoding may include adding redundancy, parity bits, or other information that can later be used to identify errors in the host data when read from the storage medium. Controller 115 may provide the host data, after encoding, via flash control channels (not shown) to write on storage mediums of storage device 105. In some implementations, ECC component 130 may perform decoding on data obtained from storage device 105.

As shown in FIG. 1, controller 115 may include a VB erase management circuit 135. VB erase management circuit 135 may manage erase operations performed on VBs. As described herein, VB erase management circuit 135 may determine that a VB (with one or more partially programmed blocks) is to be erased after detecting a power cycle of storage device 105 or detecting errors with respect to the one or more partially programmed blocks. In some examples, VB erase management circuit 135 may detect a power cycle of storage device 105. After detecting the power cycle, VB erase management circuit 135 may identify a VB. In some implementations, the VB may be a VB undergoing an erase operation at a time when the power cycle occurred. In some implementations, VB erase management circuit 135 may store information identifying the VB undergoing the erase operation at a time when the power cycle occurred. The information may be stored in a memory associated with VB erase management circuit 135 (e.g., a memory associated with controller 115). Accordingly, when the power is restored to storage device 105, VB erase management circuit 135 may access the memory to obtain the information and identify the VB undergoing the erase operation at a time when the power cycle occurred. In some examples, the VB may be part of a pool of VBs to be erased. In this regard, the VB may be a single VB undergoing the erase operation.

In some implementations, VB erase management circuit 135 may identify the VB based on a block included in the VB. In some examples, host device 110 may issue an erase command indicating that an erase operation is to be performed on the block. In this regard, the VB may be identified based on the erase command indicating that the erase operation is to be performed on the block included in the VB. In some examples, controller 115 may initiate an erase operation on the block as part of a wear leveling operation or as part of a garbage collection operation. In this regard, the VB may be identified based on controller 115 initiating the erase operation on the block (included in the VB) as part of the wear leveling operation or as part of the garbage collection operation. In some examples, the VB may be identified based on the VB being part of a pool of VBs to be erased. VB erase management circuit 135 may determine whether the VB is an open VB or a closed VB based on VB information 140.

Based on determining that the VB is an open VB, controller 115 may determine to program dummy data to unprogrammed wordlines of the one or more partially programmed blocks prior to performing an erase operation on the VB. Alternatively, based on determining that the VB is an open VB, controller 115 may determine to perform a flash write operation on the one or more partially programmed blocks. In some examples, the flash write operation may be performed instead of the write operation of dummy data if a quantity of unprogrammed wordlines (of the VB) exceeds a quantity threshold. In some examples, the flash write operation may be performed (instead of the write operation of dummy data) if one or more other operations are to be performed within a relatively short period of time. The one or mor other operations may be operations requested by host device 110. In some examples, the write operation of dummy data may be performed instead of the flash write operation if an available power of storage device 105 does not satisfy a power threshold (because the flash write operation consumes more power than the write operation of dummy data). In some examples, controller 115 may determine to perform the flash write operation or the write operation of dummy data based on a number of program erase cycles of the VB.

As shown in FIG. 1, memory 120 may store VB information 140. VB information 140 may include a data structure that stores information regarding multiple VBs of storage device 105. For example, for a particular VB, VB information 140 may include information indicating whether the particular VB is an open VB or is a closed VB, information whether the particular VB includes partially programmed blocks, information identifying the partially programmed blocks, information identifying unprogrammed wordlines of the partially programmed blocks, and/or information identifying P/E cycles of blocks of the VB, among other examples.

As shown in FIG. 1, storage device 105 may include storage mediums 145 (individually “storage medium 145” and collectively “storage mediums 145”). A storage medium 145 may include a non-volatile memory device. For example, the storage medium 145 may include a NAND memory device. In some situations, storage mediums 145 may be organized by data pools. A “data pool” may be used to refer to part of a storage medium 145 that stores a given type of data (e.g., single-layer cell (SLC) data, multi-layer cell (MLC) data, and triple-layer cell (TLC) data, without limitation).

As shown in FIG. 1, a storage medium 145 may include multiple dies. In some implementations, a die may include multiple planes. A plane may include multiple memory blocks (also referred to as “block”), one or more page buffers (associated with the blocks), and one or more cache buffers.

As shown in FIG. 1, a block may include programmed wordlines and unprogrammed wordlines. Accordingly, the block may be a partially programmed block. The partially programmed block may be part of an open VB and may be experiencing a read error or a write error. In an effort to prevent or mitigate the issues associated with partially programmed blocks of open VBs as described herein, controller 115 may write dummy data to the unprogrammed wordlines of the block, as described herein. In some situations, the dummy data may be written as part of a background operation (e.g., a data backup operation) regarding the data to the block. In this regard, the one or more unprogrammed wordlines may not exceed a number threshold of unprogrammed wordlines to prevent burdening the data backup operation.

Alternatively, controller 115 may perform a flash write operation on the block, as described herein. In some situations, the flash write operation may be performed as part of a background operation. In some examples, the flash write operation may be performed instead of the write operation of dummy data if a quantity of unprogrammed wordlines (of the VB) exceeds a quantity threshold. In some examples, the flash write operation may be performed (instead of the write operation of dummy data) if one or more other operations are to be performed within a relatively short period of time. The one or mor other operations may be operations requested by host device 110. In some examples, the write operation of dummy data may be performed instead of the flash write operation if an available power of storage device 105 does not satisfy a power threshold (because the flash write operation consumes more power than the write operation of dummy data). In some examples, controller 115 may perform the flash write operation or the write operation of dummy data based on a number of program erase cycles of the VB.

While examples herein may be described with respect to SLC non-volatile memory devices (1 bit per cell), implementations described herein may be applicable to other types of non-volatile memory devices, such as MLC non-volatile memory devices (2 bits per cell), TLC non-volatile memory devices (3 bits per cell), and QLC non-volatile memory devices (4 bits per cell), without limitation.

As indicated above, FIG. 1 is provided as an example. Other examples may differ from what is described with regard to FIG. 1. The number and arrangement of devices shown in FIG. 1 is provided as an example. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) shown in FIG. 1 may perform one or more functions described as being performed by another set of devices shown in FIG. 1.

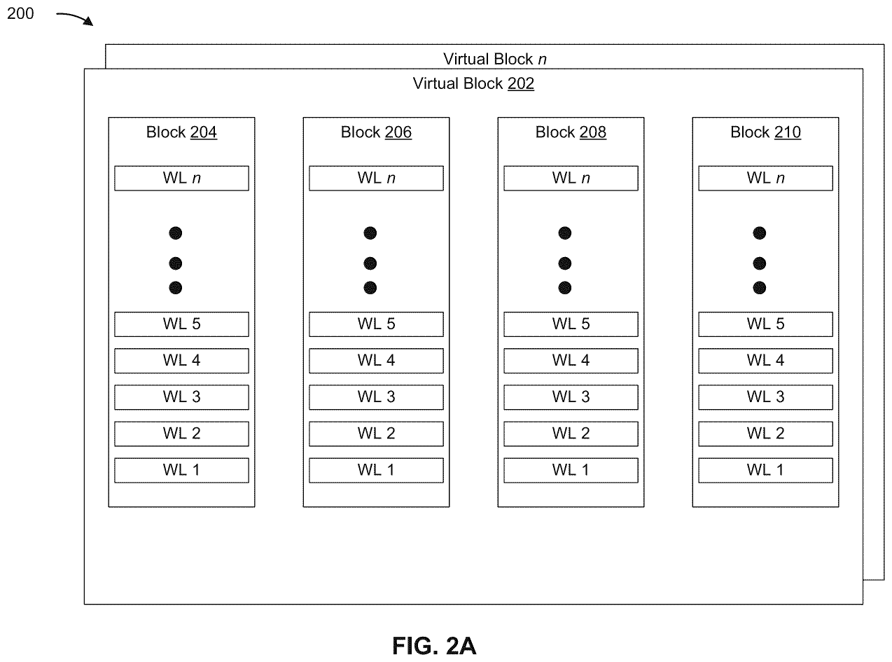

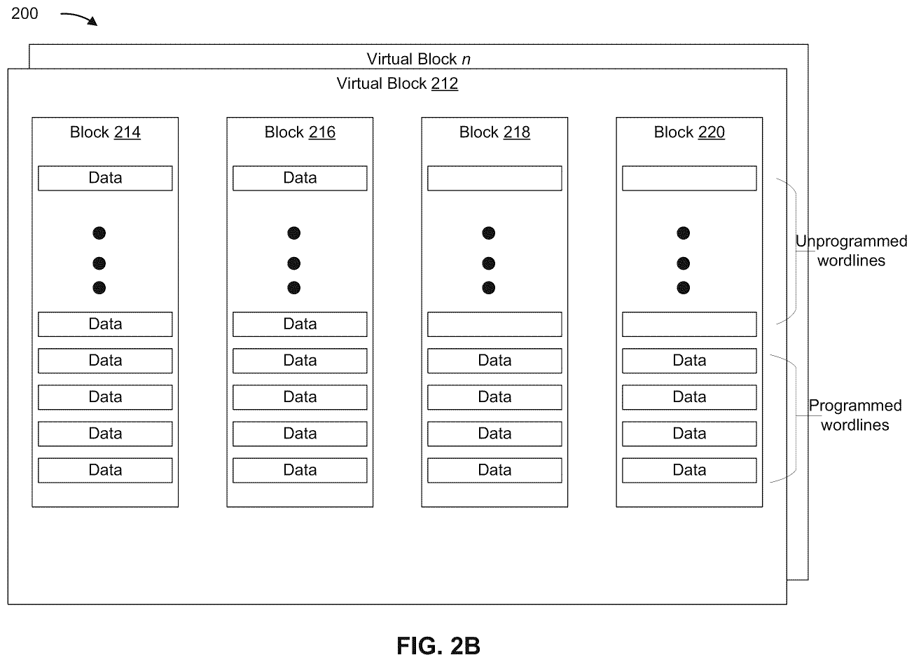

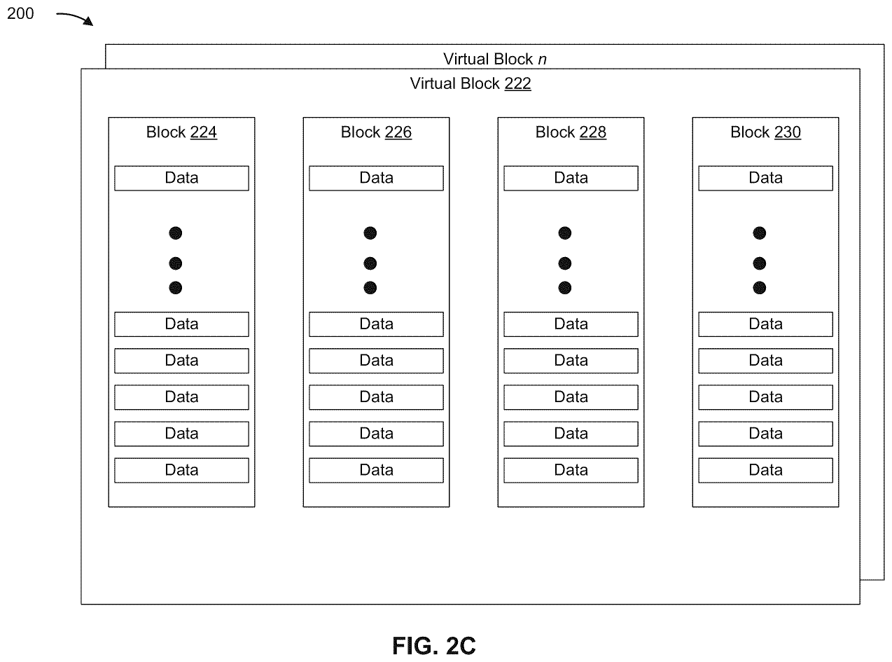

FIGS. 2A-2C are diagrams of an example 200 of a virtual block described herein. As shown in FIG. 2A, a storage device (e.g., storage device 105) may include one or more virtual blocks 202 that includes one or more physical components for storing data. For example, a virtual block 202 may include transistors organized into physical and logical units for storing data. Virtual block 202 may include a set of blocks 204, 206, 208, and 210 from different dies. In some situations, virtual block 202 may include any number of blocks. In some examples, blocks 204, 206, 208, and 210 may be part of different planes.

Blocks 204, 206, 208, and 210 may include a set of word lines (e.g. shown as word lines 1 through n). In some situations, virtual block 202 may include one or more partially programmed blocks. For example, one or more wordlines of one or more blocks may be unprogrammed. In other words, the one or more wordlines may not store user data or system data. As an example, the one or more blocks may include one or more of blocks 204, 206, 208, or 210.

As shown in FIG. 2B, the storage device (e.g., storage device 105) may include a virtual block 212. As shown in FIG. 2B, virtual block 212 may include a block 214, a block 216, a block 218, and a block 220. As an example, all wordlines of block 214 may be programmed. For instance, all wordlines of block 214 may store data (e.g., user data). Accordingly, block 214 may be a fully programmed block. Similarly to block 214, all wordlines of block 216 may be programmed (e.g., may store data). Accordingly, block 216 may be a fully programmed block. As shown in FIG. 2B, block 220 may include programmed wordlines and unprogrammed wordlines. For example, controller 115 may start performing a programming operation on a first number of wordlines (e.g., to program data from host device 110). The programming operation may be terminated or suspended before all the wordlines of block 220 are programmed. Accordingly, block 220 may include programmed wordlines and unprogrammed wordlines. Therefore, block 220 may be a partially programmed block. Similarly to block 220, block 218 may include programmed wordlines and unprogrammed wordlines. For example, controller 115 may start performing a programming operation on a first number of wordlines (e.g., to program data from host device 110). The programming operation may be terminated or suspended before all the wordlines of block 218 are programmed. Accordingly, block 218 may be a partially programmed block. Because virtual block 212 includes partially programmed blocks (e.g., block 218 and block 220), virtual block 212 may be an open virtual block. As explained herein, because virtual block 212 is an open virtual block, controller 115 may perform a write operation of dummy data or a flash write operation on virtual block 212 before an erase operation is performed on virtual block 212. As shown in FIG. 2C, the storage device (e.g., storage device 105) may include a virtual block 222. Virtual block 222 may include a block 224, a block 226, a block 228, and a block 230. As an example, all wordlines of block 224 may store data (e.g., data provided by host device 110). In other words, all wordlines of block 224 may be programmed. Accordingly, block 224 may be a fully programmed block. Similarly to block 224, all wordlines of block 226, block 228, and block 230 may be programmed (e.g., may store data). Accordingly, block 226, block 228, and block 230 may be a fully programmed block. In this regard, all wordlines of virtual block 222 may be programmed. Because virtual block 222 does not include a partially programmed block, virtual block 222 may be a closed virtual block. In other words, because all wordlines of virtual block 222 are programmed, virtual block 222 may be a closed virtual block.

As indicated above, FIGS. 2A-2C are provided as an example. Other examples may differ from what is described with regard to FIGS. 2A-2C.

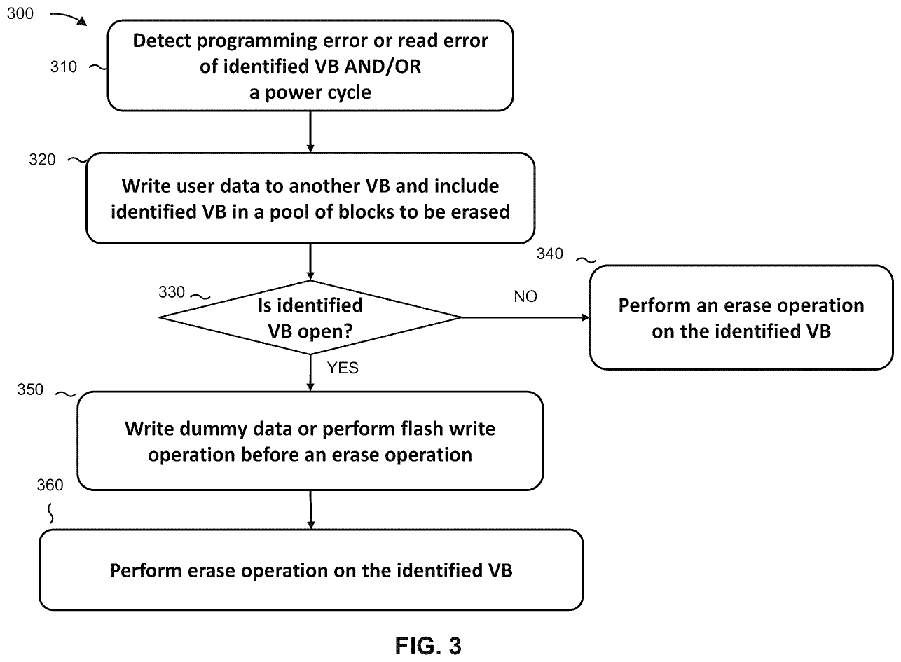

FIG. 3 is a flowchart of an example process 300 associated with performing an erase operation on partially programmed blocks of a virtual block. In some implementations, one or more process blocks of FIG. 3 may be performed by a controller (e.g., controller 115) of a storage device (e.g., storage device 105). In some implementations, one or more process blocks of FIG. 3 may be performed by another device or a group of devices separate from or including the controller, such as a storage medium (e.g., storage medium 145) and/or a host device (e.g., host device 110).

As shown in FIG. 3, process 300 may include detecting a programming error or a read error of an identified VB and/or detecting a power cycle (block 310). For example, the controller may detect a programming error during an attempt to write data to a first block of a VB (e.g., the identified VB). Additionally, or alternatively, the controller may detect a read error during an attempt to read data from the first block or a second block of the VB. In some implementations, the controller may detect a power cycle experienced by the storage device. For example, the controller may detect a power loss event on the storage device.

As further shown in FIG. 3, process 300 may include writing user data to another VB and including the identified VB in a pool of blocks to be erased (block 320). For example, the controller may write user data to another VB and may include the identified VB in a pool of blocks to be erased. The controller may write the user data to another VB and include the identified VB in the pool of blocks to e be erased based on detecting the programming error, the read error, or the power cycle.

In some examples, the controller may determine to write the user data to another VB based on detecting a threshold number of errors on one or more blocks of the identified VB. In some examples, the controller may determine to write the user data to another VB based on detecting errors on a threshold number of blocks of the identified VB. In some examples, with respect to the power cycle, the identified VB may be a VB that is pre-selected for an erase operation in the event the power cycle occurs. In some examples, the identified VB may be a VB with a least number program erase cycles. In some implementations, the identified VB may be a VB undergoing an erase operation at a time when the power cycle occurred. Accordingly, as explained herein, when the power is restored to storage device 105, the controller may access the memory to obtain the information and identify the VB undergoing the erase operation at a time when the power cycle occurred.

In some implementations, the identified VB may be pre-selected based on a block included in the identified VB. In some examples, host device 110 may issue an erase command indicating that an erase operation is to be performed on the block. In this regard, the identified VB may be pre-selected based on the erase command indicating that an erase operation is to be performed on the block included in the identified VB. In some examples, controller 115 may initiate an erase operation on the block as part of a wear leveling operation or as part of a garbage collection operation. In this regard, the identified VB may be pre-selected based on controller 115 initiating the erase operation on the block (included in the identified VB) as part of the wear leveling operation or as part of the garbage collection operation. In some implementations, the identified VB may be pre-selected based on data stored by the identified VB. For example, the identified VB may pre-selected if the identified VB stores user data. For example, the controller may be configured to ensure a data integrity of user data. Accordingly, the controller may be configured to move user data from one VB to another VB after the power cycle occurs. In some implementations, the identified VB may be pre-selected based on a number of program erase cycles of the identified VB. For example, the identified VB may be pre-selected if the number of program erase cycles satisfies a number threshold.

As further shown in FIG. 3, process 300 may include determining whether the identified VB is open (block 330). For example, after including the identified VB in the pool of VBs, the controller may determine whether the identified VB is an open VB. For example, the controller may obtain VB information (e.g., VB information 140) from a memory of the controller (e.g., memory 120). The controller may use the VB information to obtain information regarding the identified VB. Based on the information regarding the identified VB, the controller may determine whether the identified VB is an open VB.

As further shown in FIG. 3, process 300 may include performing an erase operation on the identified VB (block 340). For example, if the controller determines that the identified VB is not an open VB, the controller may perform an erase operation of the identified VB. In other words, if the controller determines the identified VB is closed VB, the controller may determine that all wordlines of the identified VB have been programmed. Accordingly, the controller may determine that an erase operation may be performed without writing dummy data or without performing a flash write operation.

As further shown in FIG. 3, process 300 may include writing dummy data or performing a flash operation before an erase operation (block 350). For example, if the controller determines that the identified VB is an open VB, the controller may determine that the identified VB includes one or more partially programmed blocks. Accordingly, the controller may determine that dummy data is to be written to the one or more partially programmed blocks. Alternatively, the controller may determine that a flash write operation is to be performed on the one or more partially programmed blocks. In some examples, the flash write operation may be performed instead of the write operation of dummy data if a quantity of unprogrammed wordlines (of the VB) exceeds a quantity threshold. In some examples, the flash write operation may be performed (instead of the write operation of dummy data) if one or more other operations are to be performed within a relatively short period of time. The one or mor other operations may be operations requested by host device 110. In some examples, the write operation of dummy data may be performed instead of the flash write operation if an available power of storage device 105 does not satisfy a power threshold (because the flash write operation consumes more power than the write operation of dummy data). In some examples, controller 115 may determine to perform the flash write operation or the write operation of dummy data based on a number of program erase cycles of the VB.

As further shown in FIG. 3, process 300 may include performing an erase operation on the identified VB (block 360). For example, after the dummy data has been written to the one or more partially programmed blocks or after the flash write operation has been performed, the controller may perform the erase operation on the VB. For instance, the controller may perform the erase operation on the blocks of the VB.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

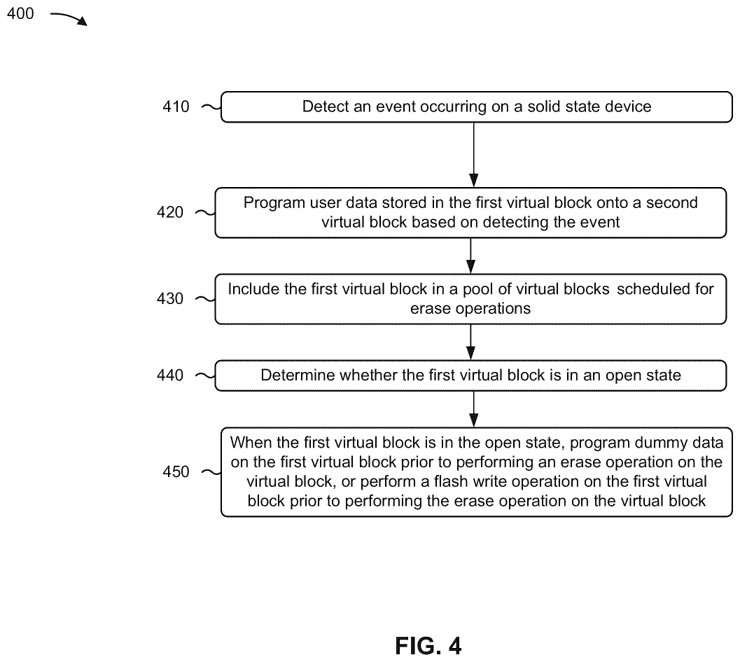

FIG. 4 is a flowchart of an example process 400 associated with performing an erase operation on partially programmed blocks of a virtual block. In some implementations, one or more process blocks of FIG. 3 may be performed by a controller (e.g., controller 115) of a storage device (e.g., storage device 105). In some implementations, one or more process blocks of FIG. 3 may be performed by another device or a group of devices separate from or including the controller, such as a storage medium (e.g., storage medium 145).

As shown in FIG. 4, process 400 may include detecting an event occurring on a solid state device, wherein the event includes at least one of: a program error on a physical block of a first virtual block, a read error on the physical block, or a power cycle of the solid state drive (block 410). For example, the controller may detect an event occurring on a solid state device, wherein the event includes at least one of: a program error on a physical block of a first virtual block, a read error on the physical block, or a power cycle of the solid state drive, as described above. In some implementations, the event includes at least one of: a program error on a physical block of a first virtual block, a read error on the physical block, or a power cycle of the solid state drive.

As further shown in FIG. 4, process 400 may include programming user data stored in the first virtual block onto a second virtual block based on detecting the event (block 420). For example, the controller may program user data, of the first virtual block, on a second virtual block based on detecting the event, as described above.

As further shown in FIG. 4, process 400 may include including the first virtual block in a pool of virtual blocks scheduled for erase operations (block 430). For example, the controller may include the first virtual block in a pool of virtual blocks scheduled for erase operations, as described above.

As further shown in FIG. 4, process 400 may include determining whether the first virtual block is in an open state (block 440). For example, the controller may determine whether the first virtual block is in an open state, as described above.

As further shown in FIG. 4, process 400 may include when the first virtual block is in the open state: programming dummy data on the first virtual block prior to performing an erase operation on the virtual block, or performing a flash write operation on the first virtual block prior to performing the erase operation on the virtual block (block 450). For example, the controller may when the first virtual block is in the open state: programming dummy data on the first virtual block prior to performing an erase operation on the virtual block, or performing a flash write operation on the first virtual block prior to performing the erase operation on the virtual block, as described above.

In some implementations, process 400 includes performing the erase operation on the virtual block after programming the dummy data or performing the flash write operation.

In some implementations, process 400 includes programming the dummy data as part of a background activity, or performing a flash write operation as part of the background activity.

In some implementations, process 400 includes programming the dummy data on unprogrammed wordlines of the physical block.

In some implementations, programming the dummy data comprises programming data of a random pattern on the unprogrammed wordlines of the physical block.

In some implementations, programming the dummy data comprises programming data of a fixed pattern on the unprogrammed wordlines of the physical block.

In some implementations, performing the flash write operation comprises performing the flash write operation on an entirety of the physical block.

In some implementations, process 400 includes determining that the virtual block is not in the open state, and performing the erase operation on the virtual block without programming the dummy data or without performing the flash write operation.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
detecting an event occurring on a solid state drive,
wherein the event includes at least one of:
a program error on a physical block of a first virtual block,
a read error on the physical block, or
a power cycle of the solid state drive;
programming user data stored in the first virtual block onto a second virtual block based on detecting the event;
including the first virtual block in a pool of virtual blocks scheduled for erase operations;
determining whether the first virtual block is in an open state; and
when the first virtual block is in the open state:
programming dummy data on the first virtual block prior to performing an erase operation on the virtual block, or
performing a flash write operation on the first virtual block prior to performing the erase operation on the virtual block.

2. The method of claim 1, comprising:
performing the erase operation on the virtual block after programming the dummy data or performing the flash write operation.

3. The method of claim 1, comprising:
programming the dummy data as part of a background activity; or
performing the flash write operation as part of the background activity.

4. The method of claim 1, comprising:
programming the dummy data on unprogrammed wordlines of the physical block.

5. The method of claim 4, wherein programming the dummy data comprises:
programming data of a random pattern on the unprogrammed wordlines of the physical block.

6. The method of claim 4, wherein programming the dummy data comprises:
programming data of a fixed pattern on the unprogrammed wordlines of the physical block.

7. The method of claim 1, wherein performing the flash write operation comprises:
performing the flash write operation on an entirety of the physical block.

8. The method of claim 1, comprising:
determining that the virtual block is not in the open state; and
performing the erase operation on the virtual block without programming the dummy data or without performing the flash write operation.

9. A system comprising:
a controller to:
detect an event associated with a virtual block,
wherein the event includes at least one of:
a program error on a physical block of the virtual block,
a read error on the physical block, or
a power cycle of a storage device that includes the virtual block;
determine whether the virtual block is in an open state;
program data on the virtual block, prior to performing an erase operation on the virtual block, when the virtual block is in the open state; and
perform the erase operation on the virtual block, without programming the data on the virtual block, when the virtual block is not in the open state.

10. The system of claim 9, wherein, to program the data, the controller is to:
program dummy data as part of a background activity.

11. The system of claim 10, wherein, to program the dummy data, the controller is to:
program the dummy data on unprogrammed wordlines of the physical block.

12. The system of claim 11, wherein, to program the dummy data, the controller is to:
program data of a random pattern on the unprogrammed wordlines of the physical block.

13. The system of claim 11, wherein, to program the dummy data, the controller is to:
program data of a fixed pattern on the unprogrammed wordlines of the physical block.

14. The system of claim 9, wherein, to program the data, the controller is to:
perform a flash write operation as part of a background activity.

15. A non-transitory computer-readable medium storing a set of instructions, the set of instructions comprising:
one or more instructions that, when executed by one or more processors of a controller, cause the controller to:
detect an event associated with a first virtual block,
wherein the event includes at least one of:
a program error on a physical block of the first virtual block,
a read error on the physical block, or
a power cycle of a storage device that includes the first virtual block;
program user data stored in the first virtual block onto a second virtual block based on detecting the event; and
program data on the first virtual block, prior to performing an erase operation on the first virtual block, when the first virtual block is in an open state.

16. The non-transitory computer-readable medium of claim 15, wherein, to program the data, the controller is to:
program dummy data as part of a background activity.

17. The non-transitory computer-readable medium of claim 16, wherein, to program the dummy data, the controller is to:
program the dummy data on unprogrammed wordlines of the physical block.

18. The non-transitory computer-readable medium of claim 17, wherein, to program the dummy data, the controller is to:
program data of a random pattern on the unprogrammed wordlines of the physical block.

19. The non-transitory computer-readable medium of claim 17, wherein, to program the dummy data, the controller is to:
program data of a fixed pattern on the unprogrammed wordlines of the physical block.

20. The non-transitory computer-readable medium of claim 15, wherein, to program the data, the controller is to:
perform a flash write operation as part of a background activity.
